(19) United States
(12) Patent Application Publication
(10) Pub. No.: US 2024/0006184 A1
(43) Pub. Date: Jan. 4, 2024

(54) METHOD OF MANUFACTURING SEMICONDUCTOR DEVICE, DISPLAY METHOD, NON-TRANSITORY COMPUTER-READABLE RECORDING MEDIUM AND SUBSTRATE PROCESSING APPARATUS

(71) Applicant: Kokusai Electric Corporation, Tokyo (JP)

(72) Inventors: Junichi KAWASAKI, Toyama-shi (JP); Shinichiro MORI, Toyama-shi (JP); Yasuhiro JOHO, Toyama-shi (JP); Satomi YAMAZAKI, Toyama-shi (JP)

(73) Assignee: Kokusai Electric Corporation, Tokyo (JP)

(21) Appl. No.: 18/469,679

(22) Filed: Sep. 19, 2023

Related U.S. Application Data
(63) Continuation of application No. PCT/JP21/11786, filed on Mar. 22, 2021.

(51) Int. Cl. H01L 21/31; H01L 21/67; G05B 19/4099

(52) U.S. Cl. CPC H01L 21/31; H01L 21/67017; G05B 19/4099; G05B 2219/45031

(57) ABSTRACT

According to some embodiments of the present disclosure, a gas line whose gas flow rate is to be edited by a user can be confirmed. There is provided a technique that includes: (a) displaying, on a recipe edit screen, a parameter setting region configured to set control parameters including a gas flow rate of a flow rate controller and a gas pattern screen configured to set an opening/closing state of a valve; (b) editing the recipe on the recipe edit screen; and (c) processing a substrate by performing the recipe edited in (b). When the gas flow rate of the flow rate controller is set on the parameter setting region, a flow rate controller on the gas pattern screen in association with the flow rate controller whose gas flow rate is set on the parameter setting region is clearly specified.

### CROSS-REFERENCE TO RELATED PATENT APPLICATION

This application is a bypass continuation application of PCT International Application No. PCT/JP2021/011786, filed on Mar. 22, 2021, in the WIPO, the entire contents of which are hereby incorporated by reference.

### BACKGROUND

### 1. Field

The present disclosure relates to a method of manufacturing a semiconductor device, a display method, a non-transitory computer-readable recording medium and a substrate processing apparatus.

### 2. Related Art

In general, a substrate processing apparatus is provided with a plurality of gas lines through which various gases such as a source gas, an inert gas and a reactive gas are supplied into a process chamber. In the substrate processing apparatus, a predetermined processing may be performed by opening and closing valves of the gas lines to supply the various gases through from a gas supply system (gas suppler) to a substrate (hereinafter, also referred to as a “wafer”) in the process chamber.

According to some related arts, there is disclosed a substrate processing apparatus capable of creating a recipe by collectively displaying, on a recipe edit screen, a region configured to set control parameters, a region configured to set a valve opening/closing state and a region for displaying various parameter information.”

According to another related arts, there is disclosed a substrate processing apparatus capable of creating the recipe by collectively displaying, on the recipe edit screen, a recipe editing region for editing a step of a recipe file, a sub-region for displaying a combination file associated with the recipe and a command selection region for selecting a recipe editing command and performing an actual editing action.

According to still another related arts, there is disclosed a substrate processing apparatus capable of switching the recipe edit screen to a gas pattern screen and setting the valve opening/closing state.

However, when a user sets a gas flow rate on the recipe edit screen, the user may set the gas flow rate for a gas line other than a desired gas line among the gas lines by mistake.

### SUMMARY

According to the present disclosure, there is provided a technique capable of confirming a gas line whose gas flow rate is to be edited by a user.

According to one embodiment of the present disclosure, there is provided a technique that includes: (a) displaying, on a recipe edit screen configured to create a recipe including a plurality of steps, a parameter setting region configured to set control parameters at least including a gas flow rate of a flow rate controller and a gas pattern screen configured to set an opening/closing state of a valve; (b) editing the recipe on the recipe edit screen; and (c) processing a substrate by performing the recipe edited in (b), wherein, in (b), when the gas flow rate of the flow rate controller is set on the parameter setting region, a flow rate controller on the gas pattern screen in association with the flow rate controller whose gas flow rate is set on the parameter setting region is clearly specified.

### BRIEF DESCRIPTION OF THE DRAWINGS

FIG. 1 is a diagram schematically illustrating a vertical cross-section of a process furnace 202 of a substrate processing apparatus 10 preferably used in one or more embodiments of the present disclosure.

FIG. 2 is a block diagram schematically illustrating a configuration of a controller 240 and related components of the substrate processing apparatus 10 preferably used in the embodiments of the present disclosure.

FIG. 3 is a diagram schematically illustrating a display example of a recipe edit screen 20 displayed when editing a recipe.

FIG. 4 is a diagram schematically illustrating an enlarged view of a step setting region 30 of the recipe edit screen 20 shown in FIG. 3.

FIG. 5 is a diagram schematically illustrating an enlarged view of a step contents setting region 40 of the recipe edit screen 20 shown in FIG. 3.

FIG. 6 is a diagram schematically illustrating a display example of an alarm display in a case where a valve interlock condition is met when setting an opening/closing state of a valve 243a on a gas pattern screen 42.

FIG. 7 is a diagram schematically illustrating a display example of the valve interlock condition in a case where a valve for which the valve interlock condition is set is long-pressed on the gas pattern screen 42.

FIG. 8 is a diagram schematically illustrating a display example when an arbitrary valve is selected on the gas pattern screen 42 and gas pipes connected to the selected valve are clearly specified.

FIG. 9 is a flow chart schematically illustrating a process flow when a recipe editing is started in the substrate processing apparatus 10 according to the embodiments of the present disclosure.

FIG. 10 is a flow chart schematically illustrating a process flow when a gas setting is performed in the substrate processing apparatus 10 according to the embodiments of the present disclosure.

FIG. 11 is a flow chart schematically illustrating a process flow when settings are changed in a parameter setting region 41 or the gas pattern screen 42 on the recipe edit screen 20 in the substrate processing apparatus 10 according to the embodiments of the present disclosure.

FIG. 12 is a flow chart schematically illustrating a process flow when a mass flow controller (MFC) is displayed in association with the parameter setting region 41 or the gas pattern screen 42 on the recipe edit screen 20 in the substrate processing apparatus 10 according to the embodiments of the present disclosure.

FIG. 13 is a flow chart schematically illustrating a process flow when the arbitrary valve is selected on the gas pattern screen 42 on the recipe edit screen 20 in the substrate processing apparatus 10 according to the embodiments of the present disclosure.

FIG. 14 is a flow chart schematically illustrating a process flow when the step setting region 30 of the recipe edit screen 20 is displayed in the substrate processing apparatus 10 according to the embodiments of the present disclosure.

### DETAILED DESCRIPTION

### Embodiments of Present Disclosure

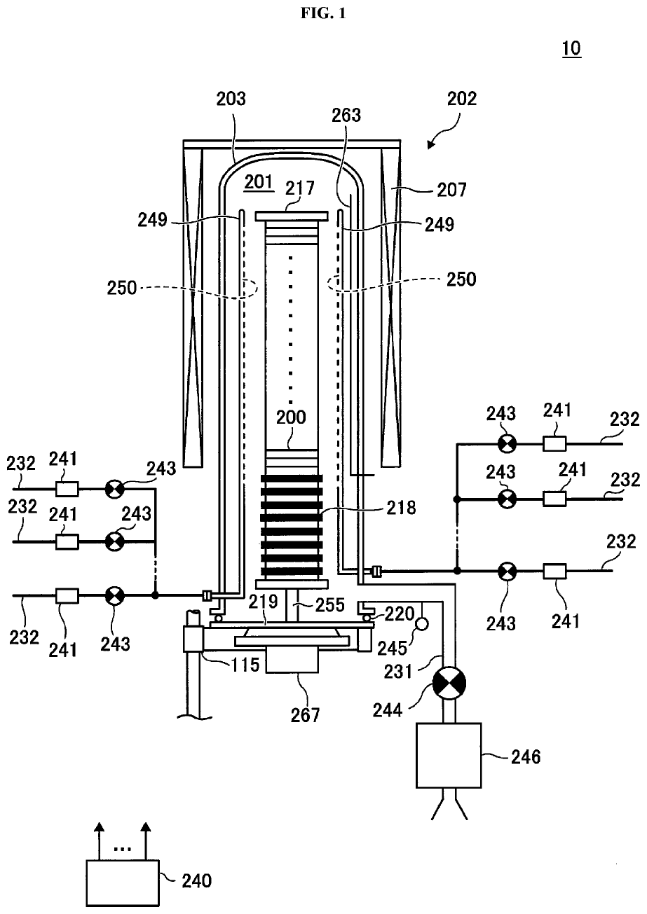

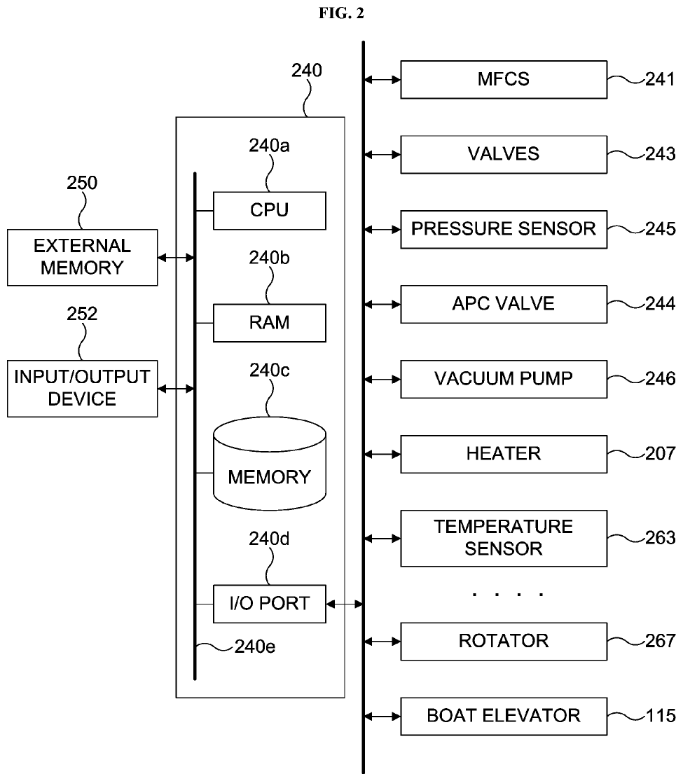

Hereinafter, one or more embodiments (also simply referred to as “embodiments”) of the technique of the present disclosure will be described with reference to the drawings. First, a substrate processing apparatus 10 according to the embodiments of the present disclosure will be described with reference to FIGS. 1 and 2. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

The substrate processing apparatus 10 includes a process furnace 202 in which a wafer 200 serving as a substrate transferred into a housing is processed. As shown in FIG. 1, the process furnace 202 includes a heater 207 serving as a heating structure (which is a temperature regulator or a temperature adjusting structure). The heater 207 is of a cylindrical shape, and is vertically installed while being supported by a support plate (not shown). The heater 207 also functions as an activator (also referred to as an “exciter”) capable of activating (or exciting) a gas by a heat.

A reaction tube 203 is provided in an inner side of the heater 207 to be aligned in a manner concentric with the heater 207. For example, the reaction tube 203 is made of a heat resistant material such as quartz (SiO₂) and silicon carbide (SiC). For example, the reaction tube 203 is of a cylindrical shape with a closed upper end and an open lower end. A process chamber 201 is provided in a hollow cylindrical portion of the reaction tube 203. The process chamber 201 is configured to be capable of accommodating a plurality of wafers including the wafer 200. Hereinafter, the plurality of wafers including the wafer 200 may also be simply referred to as “wafers 200”. The wafer 200 is processed in the process chamber 201.

A plurality of nozzles 249 are provided in the process chamber 201 so as to penetrate a lower side wall of the reaction tube 203. A plurality of gas supply pipes 232 are connected to the nozzles 249, respectively. Hereinafter, each of the nozzles 249 may also be referred to as a “nozzle 249”, and each of the gas supply pipes 232 may also be referred to as a “gas supply pipe 232”.

A mass flow controller (also simply referred to as an “MFC”) 241 serving as a flow rate controller (flow rate control structure) and a valve 243 serving as an opening/closing valve are sequentially installed at the gas supply pipe 232 in this order from an upstream side to a downstream side of the gas supply pipe 232 in a gas flow direction. That is, a plurality of MFCs including the MFC 241 and a plurality of valves including the valve 243 are provided at the gas supply pipes 232, respectively. Hereinafter, the plurality of MFCs including the MFC 241 may also be simply referred to as “MFC 241”, and the plurality of valves including the valve 243 may also be simply referred to as “valve 243”.

Various gases such as a source gas, an inert gas and a reactive gas can supplied into the process chamber 201 through the gas supply pipe 232 provided with the MFC 241 and the valve 243 and the nozzle 249.

For example, an exhaust pipe 231 through which an inner atmosphere of the process chamber 201 is exhausted is connected to the lower side wall of the reaction tube 203 at a location below the gas supply pipe 232. An exhaust apparatus 246 constituted by a vacuum pump is connected to the exhaust pipe 231 through a pressure sensor 245 and an APC (Automatic Pressure Controller) valve 244. Hereinafter, the exhaust apparatus 246 may also be referred to as a “vacuum pump 246”. The pressure sensor 245 serves as a pressure detector (pressure detection structure) to detect an inner pressure of the process chamber 201, and the APC valve 244 serves as a pressure regulator (pressure adjusting structure). With the vacuum pump 246 in operation, the APC valve 244 may be opened or closed to perform a vacuum exhaust operation of the process chamber 201 or stop the vacuum exhaust operation. With the vacuum pump 246 in operation, the inner pressure of the process chamber 201 may be adjusted by adjusting an opening degree of the APC valve 244 based on pressure information detected by the pressure sensor 245. An exhauster (which is an exhaust structure or an exhaust system) is constituted mainly by the exhaust pipe 231, the APC valve 244 and the pressure sensor 245. The exhauster may further include the vacuum pump 246.

Hereinafter, the gas supply pipes 232 and the exhaust pipe 231 may also be collectively or individually referred to as “gas pipes” or a “gas pipe”.

Further, a seal cap 219 serving as a furnace opening lid capable of airtightly sealing (or closing) a lower end opening of the reaction tube 203 is provided under the reaction tube 203. For example, the seal cap 219 is made of a metal material such as SUS, and is of a disk shape. An O-ring 220 serving as a seal is provided on an upper surface of the seal cap 219 so as to be in contact with the lower end of the reaction tube 203. A rotator (which is a rotating structure) 267 configured to rotate a boat 217 described later is provided under the seal cap 219. For example, a rotating shaft 255 of the rotator 267 is connected to the boat 217 through the seal cap 219. As the rotator 267 rotates the boat 217, the wafers 200 accommodated in the boat 217 are rotated.

The seal cap 219 is configured to be elevated or lowered in a vertical direction by a boat elevator 115 serving as an elevating structure provided outside the reaction tube 203. The boat elevator 115 serves as a transfer device (which is a transfer structure or a transfer system) capable of transferring (loading) the boat 217 and the wafers 200 accommodated therein into the process chamber 201 and capable of transferring (unloading) the boat 217 and the wafers 200 accommodated therein out of the process chamber 201 by elevating and lowering the seal cap 219.

The boat 217 (which is a substrate support or a substrate retainer) is configured such that the wafers 200 (for example, 25 wafers to 250 wafers) are accommodated (or supported) in the vertical direction in the boat 217 while the wafers 200 are horizontally oriented with their centers aligned with one another in a multistage manner. That is, the boat 217 is configured such that the wafers 200 are arranged in the vertical direction in the boat 217 while the wafers 200 are horizontally oriented with a predetermined interval therebetween. For example, the boat 217 is made of a heat resistant material such as quartz and SiC. For example, a plurality of heat insulation plates 218 made of a heat resistant material such as quartz and SiC are supported at a lower portion of the boat 217 in a multistage manner.

A temperature sensor 263 serving as a temperature detector is installed in the reaction tube 203. A state of electric conduction to the heater 207 is adjusted based on temperature information detected by the temperature sensor 263 such that a desired temperature distribution of an inner temperature of the process chamber 201 can be obtained. The temperature sensor 263 is provided along an inner wall of the reaction tube 203.

As shown in FIG. 2, a controller 240 serving as a control device (control structure) is constituted by a computer including a CPU (Central Processing Unit) 240a, a RAM (Random Access Memory) 240b, a memory 240c and an I/O port (input/output port) 240d. The RAM 240b, the memory 240c and the I/O port 240d may exchange data with the CPU 240a through an internal bus 240e. For example, an input/output device 252 constituted by a component such as a touch panel is connected to the controller 240.

For example, the memory 240c is configured by a component such as a flash memory and a hard disk drive (HDD). For example, a control program configured to control an operation of the substrate processing apparatus 10 and a recipe such as a process recipe in which a procedure (hereinafter, also referred to as a “step”) and conditions of a predetermined processing are written may be readably stored in the memory 240c. The process recipe constituted by a plurality of steps is obtained by combining each step of the predetermined processing such that the controller 240 can execute the steps to acquire a predetermined result, and functions as a program.

Hereinafter, the recipe including the process recipe and the control program may be collectively or individually referred to as a “program”. In addition, hereinafter, the process recipe may also be simply referred to as the “recipe”. Thus, in the present specification, the term “program” may refer to the recipe alone, may refer to the control program alone or may refer to both of the recipe and the control program. The RAM 240b functions as a memory area (work area) where a program or data read by the CPU 240a is temporarily stored.

The I/O port 240d is connected to the components described above such as the MFC 241, the valve 243, the pressure sensor 245, the APC valve 244, the vacuum pump 246, the temperature sensor 263, the heater 207, the rotator 267 and the boat elevator 115.

The CPU 240a is configured to read the control program from the memory 240c and execute the read control program. In addition, the CPU 240a is configured to read the recipe from the memory 240c, for example, in accordance with an operation command inputted from the input/output device 252. In accordance with contents of the read recipe, the CPU 240a may be configured to be capable of controlling various operations such as a flow rate adjusting operation for various gases by the MFC 241, an opening and closing operation of the valve 243, an opening and closing operation of the APC valve 244, a pressure regulating operation (pressure adjusting operation) by the APC valve 244 based on the pressure sensor 245, a start and stop operation of the vacuum pump 246, a temperature adjusting operation by the heater 207 based on the temperature sensor 263, an operation of adjusting a rotation and a rotation speed of the boat 217 by the rotator 267, and an elevating and lowering operation of the boat 217 by the boat elevator 115.

The controller 240 may be embodied by installing the above-described program stored in an external memory 250 into the computer. For example, the external memory 250 may include a magnetic disk such as the HDD, an optical disk such as a CD, a magneto-optical disk such as an MO and a semiconductor memory such as a USB memory. The memory 240c or the external memory 250 may be embodied by a non-transitory computer readable recording medium. Hereafter, the memory 240c and the external memory 250 may be collectively or individually referred to as a “recording medium”. Thus, in the present specification, the term “recording medium” may refer to the memory 240c alone, may refer to the external memory 250 alone, or may refer to both of the memory 240c and the external memory 250. Instead of the external memory 250, a communication structure such as the Internet and a dedicated line may be used for providing the program to the computer.

When editing (or creating) the recipe including the plurality of steps, the substrate processing apparatus 10 according to the present embodiments is configured to display, on a recipe edit screen 20, a parameter setting region 41 configured to set control parameters and a gas pattern screen 42 including valves or the gas pipes. For example, when a control parameter of the MFC (flow rate controller) is set in the parameter setting region 41, the substrate processing apparatus 10 according to the present embodiments is capable of clearly specifying (clearly indicating) an icon indicating an MFC 241 within the gas pattern screen 42 in association with the MFC whose control parameter is set.

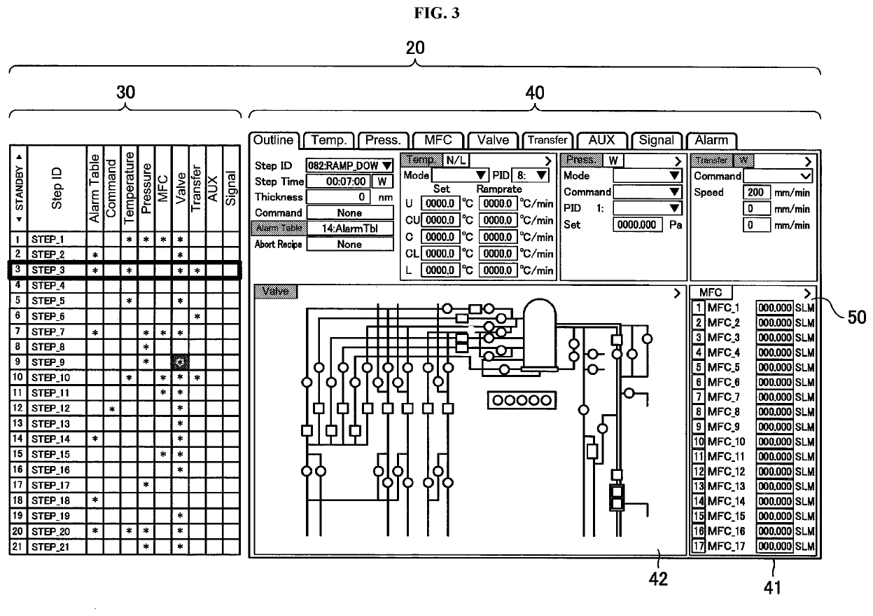

The recipe edit screen 20 shown in FIG. 3 is provided with a step setting region 30 and a step contents setting region 40. When a user selects a step to be edited in the step setting region 30 on a left side of FIG. 3, contents of the step selected by the user is displayed in the step contents setting region 40 on a right side of FIG. 3. In the step contents setting region 40, the parameter setting region 41 configured to set the control parameters and the gas pattern screen 42 configured to set an opening/closing state of the valve such as the valve 243 (also referred to as a “valve opening/closing state”) are displayed.

That is, the recipe edit screen 20 is configured such that the parameter setting region 41 and the gas pattern screen 42 are displayed for each step. Further, the recipe edit screen 20 is provided with the step setting region 30 configured to set the steps of the gas pattern screen 42 and the steps of the parameter setting region 41 to be displayed.

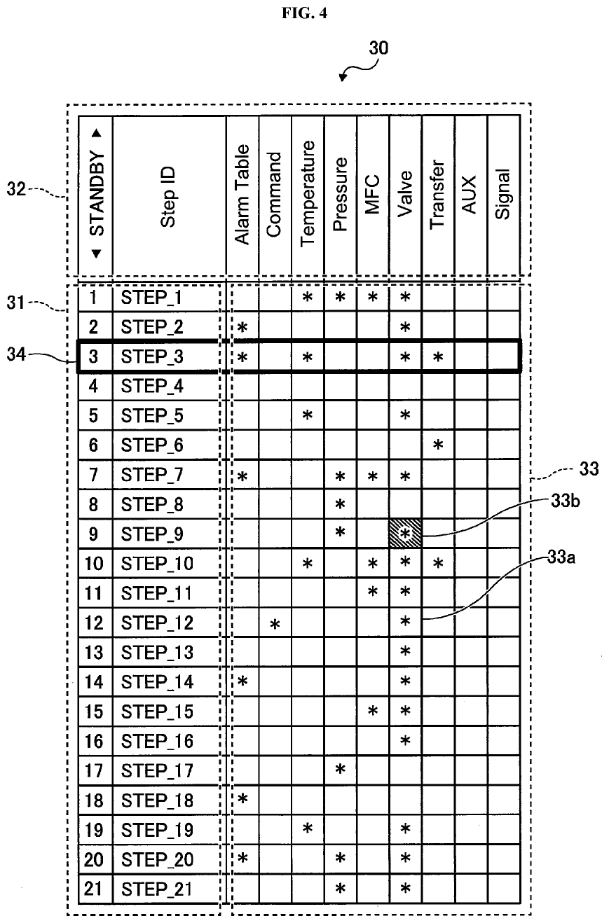

As shown in FIG. 4, the step setting region 30 is of a two-dimensional matrix format in which the steps are displayed in a vertical axis region 31 and item types are displayed in a horizontal axis region 32. When a step to be edited is selected in the vertical axis region 31, a selection display frame 34 is displayed to clearly specify the step currently selected as described above.

The step setting region 30 is configured to display whether or not a setting of the control parameters is changed for each item of each step. In an example shown in FIG. 4, in a matrix display region 33 of the step setting region 30, items 33a that changed are marked with an asterisk *.

Further, when the control parameters are set so as to meet (or match) an interlock condition, an alarm (also referred to as a “warning”) is displayed in the step setting region 30. According to the present embodiments, the interlock condition may refer to setting contents that cause a problem in the substrate processing apparatus 10. As the interlock condition, the contents set in advance are stored in the external memory 250 of the controller 240. In the example shown in FIG. 4, in the matrix display region 33 of the step setting region 30, a background color of an item 33b whose control parameters are set to meet the interlock condition is displayed in an alarm color (also referred to as a “warning color”) as an alarm display (also referred to as a “warning display”).

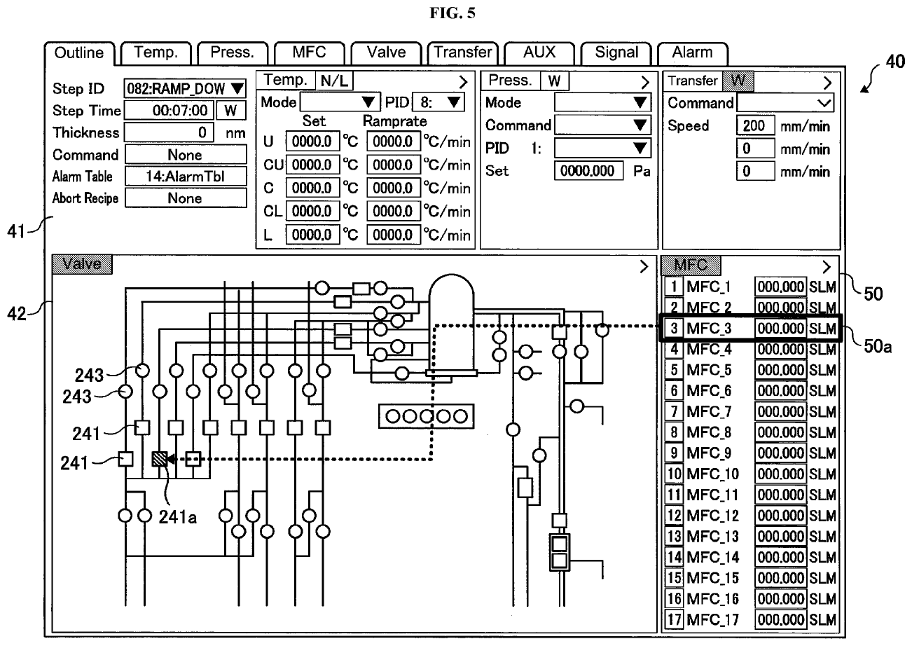

In an example shown in FIG. 5, nine tabs including “outline”, “Temp” (which indicates a temperature), “Press.” (which indicates a pressure), “MFC”, “Valve”, “Transfer”, “AUX” (which indicates an external equipment)”, “signal”, and “alarm” are displayed.

FIG. 5 schematically illustrates a state in which the “outline” tab is selected. The “outline” tab is a tab showing an overview of the contents of the selected step. In FIG. 5, the parameter setting region 41 configured to set main control parameters such as the temperature, the pressure, the transfer and the MFC and the gas pattern screen 42 configured to set the opening/closing state of the valve such as the valve 243 are displayed.

As shown in FIG. 5, tabs other than the “outline” tab are constituted by a plurality of tabs divided for a type of each control parameter. When each of the “Temp.” tab, the “Press.” tab, the “MFC” tab, the “Valve” tab, the “Transfer” tab, the “AUX” tab (which indicates the external equipment), the “Signal” tab and the “Alarm” tab is selected, a setting region for the control parameters of each item is displayed.

For example, the control parameters related to “temperature” may include: “a control mode to be used in the step”, “a designation of a control table”, “a setting value of a temperature zone”, “a designation of a ramp rate”, “a setting of a presence or absence of a step end condition” and the like.

For example, the control parameters related to “Press.” may include “a control mode used in the step”, “a designation of a control table”, “a designation of a pressure command and a setting value”, “a setting of a presence or absence of a step end condition” and the like.

For example, the control parameters related to “MFC” may include “a setting value for each MFC”, “a designation of a ramp rate”, “a setting of a presence or absence of a step end condition” and the like.

For example, the control parameters related to “Valve” may include “a gas pattern editing (valve ON/OFF)” and the like.

For example, the control parameters related to “Transfer” may include “a designation of a loader command”, “a designation of an execution condition (for example, a speed) of a loader command to be used” and the like.

For example, the control parameters related to “AUX” (which indicates the external equipment) may include “a designation of setting values for each AUX”, “a setting of a presence or absence of a step end condition” and the like. For example, since the AUX (external external equipment) may be read-only, the controller 240 verifies (or confirms) whether a read value meets the condition for the setting value.

For example, the control parameters related to “Signal” may include “a signal ON/OFF designation” and the like. The “signal ON/OFF designation” specifically designates an ON/OFF state of a specific signal with respect to the controller 240. The controller 240 initiates or inhibits an operation in accordance with the ON/OFF state of the signal.

For example, the control parameters related to “Alarm” may include “an alarm condition” (also referred to as a “warning condition”). For example, the alarm condition specifies whether to generate the alarm for each monitor value. On the “Alarm” tab, settings in use are displayed in a form of an alarm condition table in which a plurality of alarm conditions are summarized in tabular form.

The control parameters exemplified above are merely examples, and the parameters displayed on the recipe edit screen 20 may be set as appropriate depending on the recipe.

On the gas pattern screen 42, various components such as the MFC 241, the valve 243, the process furnace 202, a vaporizer (not shown), the exhaust apparatus 246 and the pressure regulator such as the APC valve 244, each of which is displayed as an icon, are connected by a plurality of gas pipes in a manner similar to a network.

On the gas pattern screen 42, it is possible to monitor the opening/closing state indicating whether the current valve is open (in an open state) or closed (in a closed state). Specifically, by switching a display color of the valve depending on whether the valve is in the open state or in the closed state, it is possible to know whether the valve is in the open state or in the closed state.

Further, the gas pattern screen 42 is provided with an operation function for the user to switch the opening/closing state of an arbitrary valve, in addition to a monitoring function of the opening/closing state of the valve. When the user uses the operation function of the valve, by tapping an image of the valve 243 displayed on the gas pattern screen 42, it is possible to switch a state of the valve 243 between the open state and the closed state

The controller 240 is configured to be capable of creating the recipe on the recipe edit screen 20 while displaying, on the recipe edit screen 20 configured to create the recipe including the plurality of steps, the parameter setting region 41 configured to set the control parameters at least including a gas flow rate of the MFC and the gas pattern screen 42 configured to set the opening/closing state of the valve 243.

Further, when the gas flow rate of the MFC is set on a gas flow rate list 50 in the parameter setting region 41, the controller 240 is configured to clearly specify (clearly indicate) the MFC 241 on the gas pattern screen 42 in association with the MFC whose gas flow rate is set as described above. As a method of clearly specifying the MFC 241 on the gas pattern screen 42 corresponding to the MFC whose gas flow rate is set, for example, a method of changing the display color of the MFC 241 on the gas pattern screen 42, a method of changing a display size of the MFC 241, a method of changing a line type of a drawing line of the MFC 241, a method of changing a display brightness of the MFC 241 and the like may be used.

Further, for example, when the MFC 241 is selected on the gas pattern screen 42, the controller 240 is configured to clearly specify the MFC 241 on the gas flow rate list 50 in association with the MFC selected as described above. As a method of clearly specifying the MFC on the gas flow rate list 50, for example, a method of moving a selection position of a selection cursor 50a in the gas flow rate list 50 to a position of the MFC 241 selected on the gas pattern screen 42 may be used. In addition, various methods such as a method of changing the display color of the MFC on the gas flow rate list 50 and a method of changing the display size of the MFC may be used.

In the example shown in FIG. 5, in a case where the gas flow rate of an MFC indicated by “MFC_3” is set in the gas flow rate list 50 in the parameter setting region 41, the display color of an MFC 241a indicated by “MFC_3” on the gas pattern screen 42 is changed.

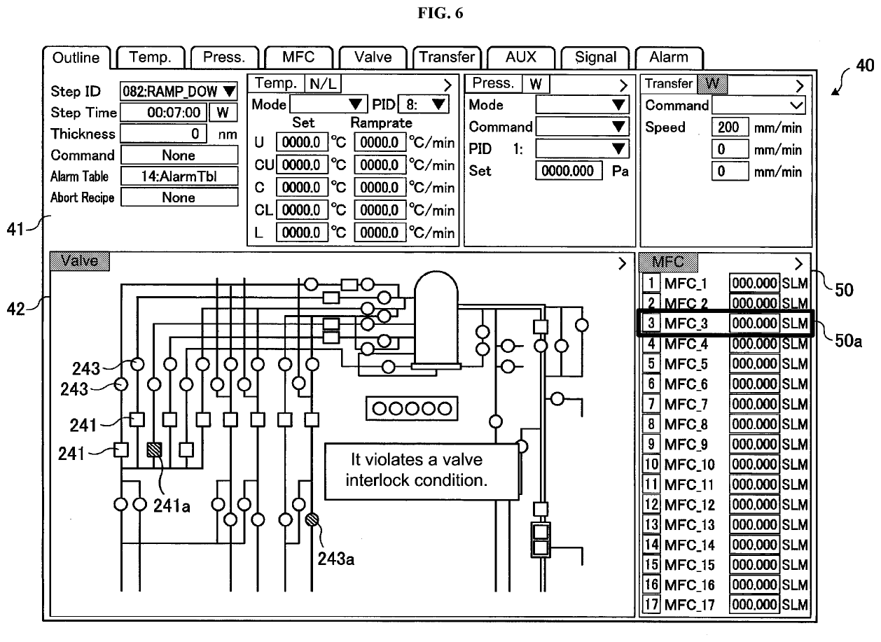

In addition, when the arbitrary valve is selected on the gas pattern screen 42, the controller 240 is configured to determine the opening/closing state of the arbitrary valve, to confirm a prohibition condition (hereinafter, also referred to as a “valve interlock condition”) for prohibiting the arbitrary valve from being opened when the arbitrary valve on the gas pattern screen 42 is set to the open state, and to perform the alarm display as shown in FIG. 6 when the arbitrary valve meets the valve interlock condition.

In an example shown in FIG. 6, when the valve 243a is set to the open state on the gas pattern screen 42, since the valve interlock condition has been met, a message such as “It violates a valve interlock condition.” is displayed as the alarm display. Further, a method of performing the alarm display is not limited to the display of the message as described above. For example, a method of changing a display color of the valve 243a, a method of changing a display size of the valve 243a, a method of changing a line type of a drawing line of the valve 243a, a method of changing a display brightness of the valve 243a and the like may be used.

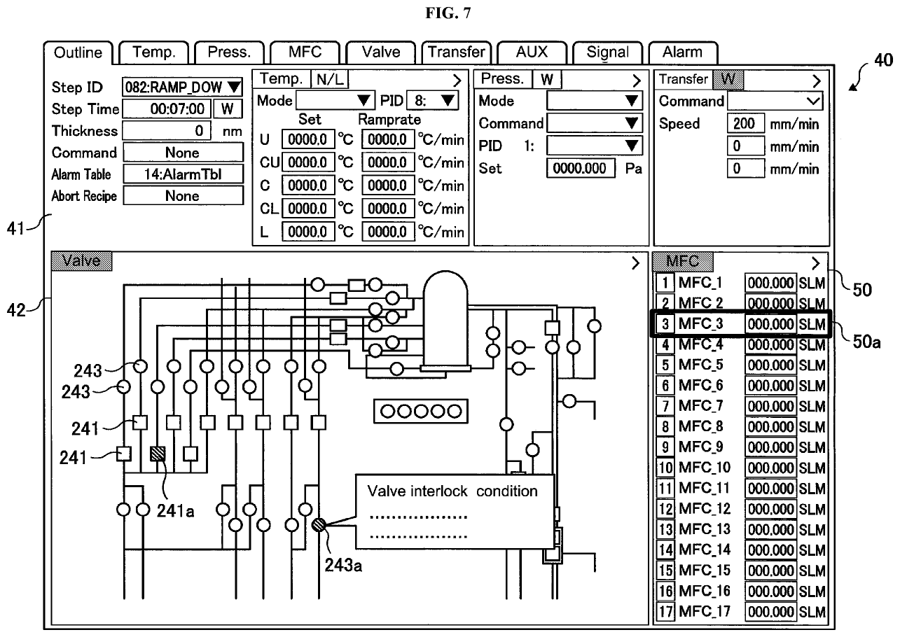

Further, when the valve 243 to which the valve interlock condition is set is selected by a long tap on the gas pattern screen 42, as shown in FIG. 7, the controller 240 is configured to display the valve interlock condition on the gas pattern screen 42. In addition, a selection for displaying the valve interlock condition is not limited to the long tap described above. For example, a selection method such as a method of right-clicking a mouse may be used as long as the selection method is different from a selection method used when setting the opening/closing state of the valve.

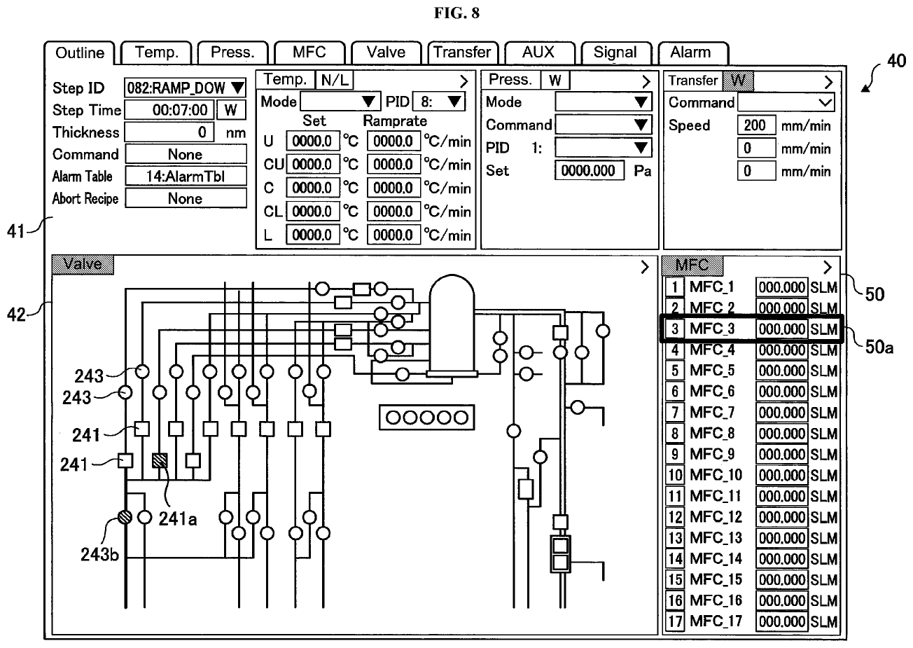

Further, when the arbitrary valve is selected on the gas pattern screen 42, as shown in FIG. 8, the controller 240 is configured to clearly specify the gas pipes connected to the arbitrary valve selected as described above.

In an example shown in FIG. 8, when a valve 243b is selected on the gas pattern screen 42, the gas pipes connected before and after the valve 243b are clearly specified by displaying the gas pipes with thick lines. Further, a method of clearly specifying the gas pipes is not limited to the thick lines as described above. For example, a method of changing a display color of the gas pipes, a method of changing a display size of the gas pipes, a method of changing a line type of a drawing line of the gas pipes, a method of changing a display brightness of the gas pipes and the like may be used.

By clearly specifying the gas pipes connected to the valve 243 selected on the gas pattern screen 42 in a manner described above, it is possible to clarify which gas pipes the valve selected by the user are related to. Thereby, it is possible to expect an effect of preventing an incorrect setting (erroneous setting).

In addition, the gas pattern screen 42 is configured such that at least the valves located within a range from a supplier (which is a supply system of a supply structure) through which a source material such as the gas is supplied to a reaction chamber (that is, the process chamber) to the exhauster (which is the exhaust system) through which an inner pressure of the reaction chamber is reduced to a vacuum atmosphere. In addition, it is possible to set various parameters of the components (which are displayed on the gas pattern screen 42) such as the MFC 241, the vaporizer, the exhauster and the pressure regulator, which are described above.

Thus, by selecting the icon displayed on the gas pattern screen 42 and displaying an operation screen, it is possible to set the parameters of various components such as the MFC 241, the vaporizer, the exhauster and the pressure regulator.

In addition, since it is possible to set various control parameters while displaying the gas pattern screen 42 on which the icons from the supplier to the exhauster are displayed, it is possible to expect the effect of preventing the incorrect setting.

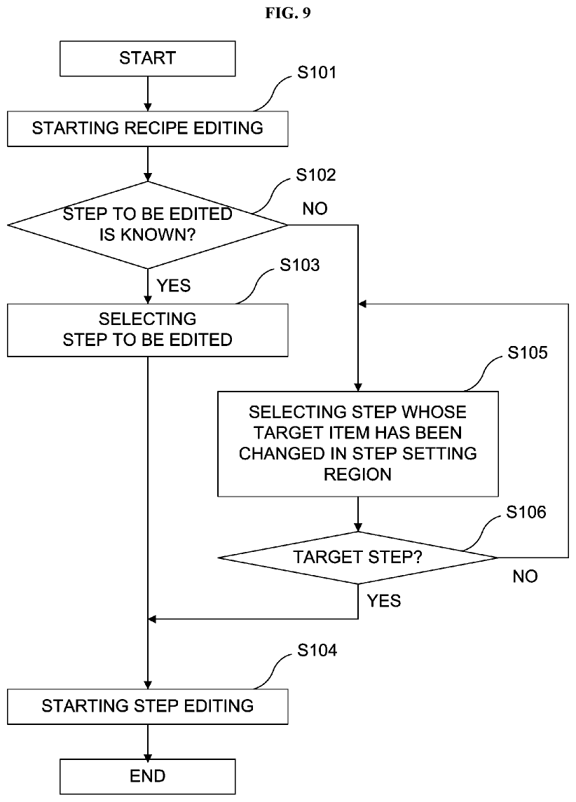

Subsequently, a process flow when a recipe editing is started in the substrate processing apparatus 10 according to the present embodiments will be described with reference to a flow chart shown in FIG. 9.

In the process flow shown in FIG. 9, first, in a step S101, the user starts the recipe editing. Then, in a step S102, it is confirmed whether the step to be edited is known. In a case where the step to be edited is known, the step to be edited is selected from the step setting region 30 in a step S103 and the contents of the step to be edited is displayed in the step contents setting region 40. Then, in a step S104, a step editing is started.

In a case where the step to be edited is not known in the step S102, in a step S105, the user selects a step whose target item has been changed in the step setting region 30. Then, in a step S106, it is confirmed whether the step selected in the step S105 is a desired step to be edited (that is, a target step).

In a case where it is confirmed in the step S106 that the step selected in the step S105 is the desired step to be edited, in the step S104, the user starts the step editing. In a case where it is confirmed in the step S106 that the step selected in the step S105 is not the desired step to be edited, the process flow returns to the step S105, and the step S105 and the step S106 are repeatedly performed until the desired step to be edited is found.

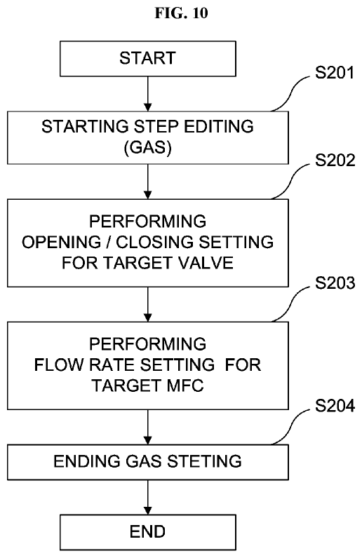

Subsequently, a process flow when a gas setting is performed in the substrate processing apparatus 10 according to the present embodiments will be described with reference to a flow chart shown in FIG. 10.

In the process flow shown in FIG. 10, first, in a step S201, the user starts the step editing so as to perform the gas setting in the step. Then, in a step S202, the user performs an opening/closing setting for a target valve. In a step S203, the user performs a flow rate setting for a target MFC. In a step S204, the gas setting is ended.

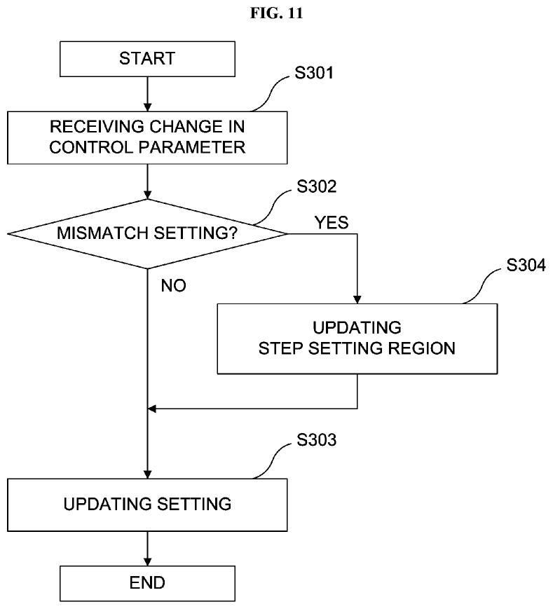

Subsequently, a process flow when the settings are changed in the parameter setting region 41 or the gas pattern screen 42 on the recipe edit screen 20 in the substrate processing apparatus 10 according to the present embodiments will be described with reference to a flow chart shown in FIG. 11.

In the process flow shown in FIG. 11, first, when the controller 240 receives a change in the setting in the parameter setting region 41 or the gas pattern screen 42 in a step S301, in a step S302, it is determined whether or not the change in the setting received as described above is a mismatch setting (inconsistent setting) that meets the interlock condition.

In a case where it is determined in the step S302 that the change in the setting is not the mismatch setting (that is, in a case where a determination result is “NO”), in a step S303, the controller 240 updates the setting reflecting the change.

In a case where it is determined in the step S302 that the change in the setting is the mismatch setting (that is, in a case where the determination result is “YES”), in a step S304, the controller 240 updates the background color of a corresponding portion of the matrix display region 33 in the step setting region 30 to the alarm color, as shown in the item 33b in FIG. 4, and notifies the user of the mismatch setting. Thereafter, in the S303, the controller 240 updates the setting reflecting the change.

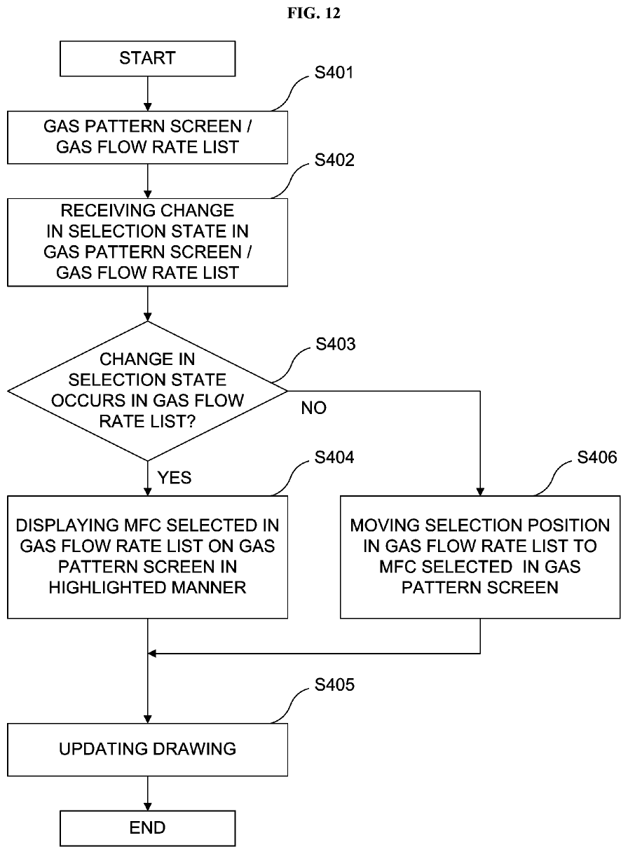

Subsequently, a process flow when the MFC is displayed in association with the parameter setting region 41 and the gas pattern screen 42 on the recipe edit screen 20 in the substrate processing apparatus 10 according to the present embodiments will be described with reference to a flow chart shown in FIG. 12.

In the process flow shown in FIG. 12, first, in a step S401, the controller 240 displays the gas pattern screen 42 and the parameter setting region 41 including the gas flow rate list 50.

Subsequently, when the controller 240 receives a change in an MFC selection state in one or more of the gas flow rate list 50 and the gas pattern screen 42 in a step S402, in a step S403, it is determined whether or not the change in the MFC selection state has occurred in the gas flow rate list 50.

Then, in a case where it is determined in the step S403 that the change in the MFC selection state has occurred in the gas flow rate list 50 (that is, in a case where a determination result is “YES”), in a step S404, the controller 240 changes the display color of the MFC 241 on the gas pattern screen 42 corresponding to the MFC selected in the gas flow rate list 50. Then, in a step S405, the controller 240 updates a drawing on the recipe edit screen 20.

On the other hand, in a case where it is determined in the step S403 that the change in the MFC selection state has not occurred in the gas flow rate list 50 (that is, in a case where the determination result is “NO”), that is, in a case where it is determined in the step S403 that the change in the MFC selection state has occurred in the gas pattern screen 42, in a step S406, the controller 240 moves the selection position of the selection cursor 50a in the gas flow rate list 50 to the corresponding MFC 241 in association with the gas pattern screen 42. Then, in the step S405, the controller 240 updates the drawing on the recipe edit screen 20.

By displaying the MFC in association with the gas flow rate list 50 in the parameter setting region 41 and the gas pattern screen 42 in a manner described above, it is possible to clarify the gas line whose gas flow rate is to be set by the user. Thereby, it is possible to expect the effect of preventing the incorrect setting. Further, a mass flow meter (also simply referred to as an “MFM”) (not shown) for measuring the flow rate of the gas may also be the same as the MFC.

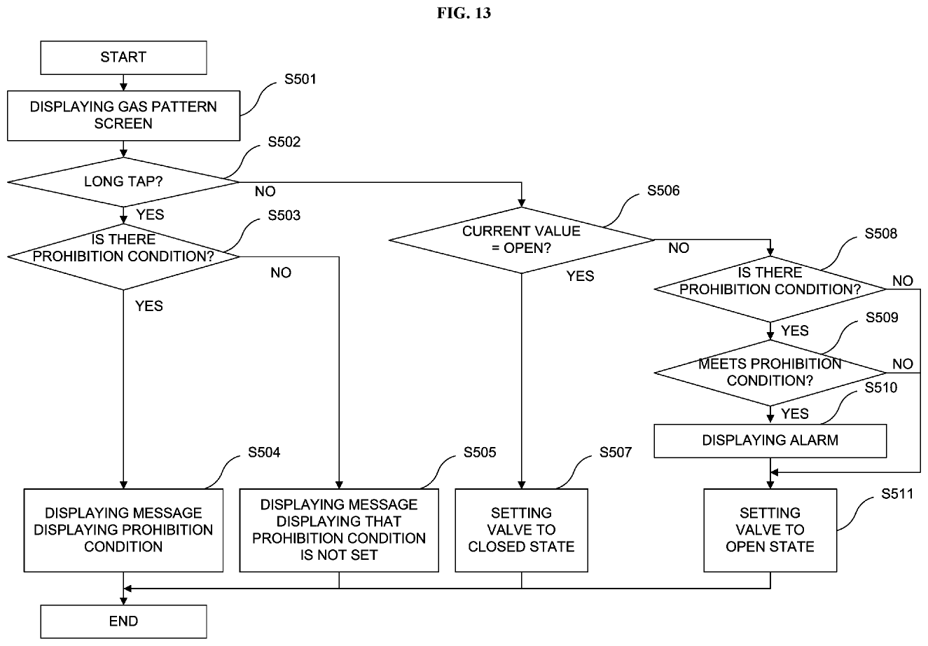

Subsequently, a process flow when the arbitrary valve is selected on the gas pattern screen 42 on the recipe edit screen 20 in the substrate processing apparatus 10 according to the present embodiments will be described with reference to a flow chart shown in FIG. 13.

In the process flow shown in FIG. 13, first, in a step S501, the controller 240 displays the gas pattern screen 42.

Subsequently, when the arbitrary valve is selected on the gas pattern screen 42, in a step S502, the controller 240 determines whether or not the arbitrary valve is selected by the long tap.

In a case where it is determined in the step S502 that the arbitrary valve is selected by the long tap (that is, in a case where a determination result is “YES”), in a step S503, the controller 240 determines whether the valve interlock condition is set for the arbitrary valve selected as described above.

In a case where it is determined in the step S503 that the valve interlock condition is set for the arbitrary valve selected as described above (that is, in a case where a determination result is “YES”), in a step S504, the controller 240 displays a message indicating the valve interlock condition (for example, on the gas pattern screen 42 as shown in FIG. 7.

In a case where it is determined in the step S503 that the valve interlock condition is not set for the arbitrary valve selected as described above (that is, in a case where the determination result is “NO”), in a step S505, the controller 240 displays a message indicating that the valve interlock condition is not set for the arbitrary valve selected as described above on the gas pattern screen 42.

In a case where it is determined in the step S502 that the arbitrary valve is not selected by the long tap (that is, in a case where the determination result is “NO”), the controller 240 considers a selection of the arbitrary valve as described above as an instruction to switch the opening/closing state of the for the arbitrary valve. Then, in a step S506, the controller 240 determines whether or not the arbitrary valve selected as described above is in the open state.

In a case where it is determined in the step S506 that the arbitrary valve selected as described above is in the open state (that is, in a case where a determination result is “YES”), in a step S507, the controller 240 set the arbitrary valve selected as described above to the closed state.

In a case where it is determined in the step S506 that the arbitrary valve selected as described above is not in the open state (that is, in a case where the determination result is “NO”), that is, it is determined in the step S506 that the arbitrary valve selected as described above is in the closed state, in a step S508, the controller 240 determines whether the valve interlock condition is set for the arbitrary valve selected as described above.

In a case where it is determined in the step S508 that the valve interlock condition is set for the arbitrary valve selected as described above (that is, in a case where a determination result is “YES”), in a step S509, the controller 240 determines whether an open setting for the arbitrary valve selected as described above meets the valve interlock condition.

In a case where it is determined in the step S509 that the open setting for the arbitrary valve selected as described above meets the valve interlock condition (that is, in a case where a determination result is “YES”), in a step S510, the controller 240 performs the alarm display on the gas pattern screen 42 as shown in FIG. 6. Then, in a step S511, the controller 240 set the arbitrary valve selected as described above to the open state.

In a case where it is determined in the step S508 that the valve interlock condition is not set for the arbitrary valve selected as described above (that is, in a case where the determination result is “No”) or in a case where it is determined in the step S509 that the open setting for the arbitrary valve selected as described above does not meet the valve interlock condition (that is, in a case where the determination result is “NO”), in the step S511, the controller 240 performs the alarm display on the gas pattern screen 42 as shown in FIG. 6. Then, in the S511, the controller 240 set the arbitrary valve selected as described above to the open state without performing the alarm display on the gas pattern screen 42.

By determining the opening/closing state for the arbitrary valve when the arbitrary valve is selected on the gas pattern screen 42, by confirming the valve interlock condition when performing the open setting for the arbitrary valve selected as described above on the gas pattern screen 42 and by performing the alarm display when the arbitrary valve selected as described above meets the valve interlock condition in a manner described above, it is possible to expect the effect of preventing the incorrect setting of the valve (that is, the arbitrary valve).

Further, when the arbitrary valve to which the valve interlock condition is set is selected by the long tap on the gas pattern screen 42, by displaying the valve interlock condition on the gas pattern screen 42 such that the user can visually recognize the valve interlock condition, it is possible to expect the effect of preventing the incorrect setting of the valve (that is, the arbitrary valve).

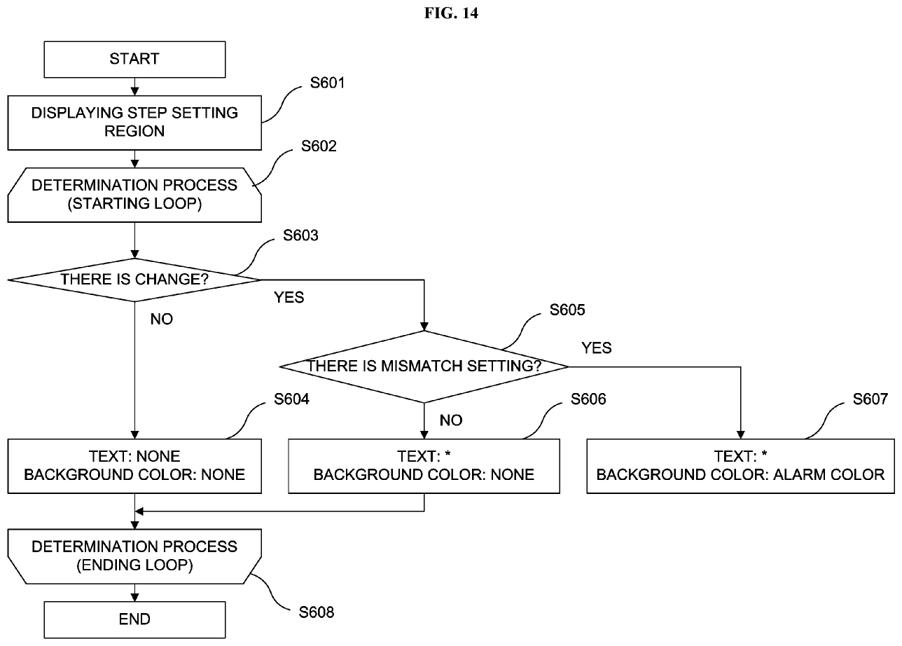

Subsequently, a process flow when the step setting region 30 is displayed on the recipe edit screen 20 of the substrate processing apparatus 10 according to the present embodiments will be described with reference to a flow chart shown in FIG. 14.

In the process flow shown in FIG. 14, first, in a step S601, the controller 240 displays the recipe edit screen 20 including the step setting region 30 and the step contents setting region 40. The recipe edit screen 20 is configured such that, when the user selects the step to be edited in the step setting region 30, the contents of the step selected as described above is displayed in the step contents setting region 40.

Subsequently, in a determination process including steps S602 through S608, the controller 240 determines whether or not there is a change point (which is a change) or a setting (mismatch setting) that meets the interlock condition for each item of each step.

In the determination process, in a step S603, for each item in each step, the controller 240 determines whether or not there is the change point in the control parameters from a reference setting for the item being determined. According to the present embodiments, the reference setting may be an initial setting stored in advance in the substrate processing apparatus 10, or may be a setting in a file created and stored by the user.

In a case where it is determined in the step S603 that there is no change from the reference setting (that is, in a case where a determination result is “NO”), in a step S604, the controller 240 sets “TEXT: NONE” and “BACKGROUND COLOR: NONE” for a relevant location of the matrix display region 33 as shown in FIG. 4.

In a case where it is determined in the step S603 that there is the change from the reference setting (that is, in a case where the determination result is “YES”), in a step S605, the controller 240 determines whether or not there is the setting of the control parameters that meets the interlock condition for the item being determined, that is, whether or not there is the mismatch setting for the item being determined.

In a case where it is determined in the step S605 that there is no mismatch setting (that is, in a case where a determination result is “NO”), in a step S606, the controller 240 sets “TEXT: *” and “BACKGROUND COLOR: NONE” for the relevant location of the matrix display region 33 as shown in the items 33a in FIG. 4.

In a case where it is determined in the step S605 that there is the mismatch setting (that is, in a case where the determination result is “YES”), in a step S607, the controller 240 sets “TEXT: *” and “BACKGROUND COLOR: ALARM COLOR” for the relevant location of the matrix display region 33 as shown in the item 33b in FIG. 4.

By configuring the recipe edit screen 20 to include the step contents setting region 40 and the step setting region 30 (which is configured to set the steps of the gas pattern screen 42 and the steps of the parameter setting region 41 to be displayed) in a manner described above, the parameter information set for each step can be visually recognized by the user in the step contents setting region 40. Thereby, it is possible to expect the effect of preventing the incorrect setting.

Further, by displaying whether or not the control parameters have been changed from the reference setting in the step setting region 30, the change in the setting of the control parameters set for each step can be visually recognized by the user. Thereby, it is possible to expect the effect of preventing the incorrect setting.

In addition, in the step setting region 30, by performing the alarm display when there is the setting of the control parameters that meets the interlock condition, it is possible for the user to completely release the interlock.

### Other Embodiments of Present Disclosure

While the technique of the present disclosure is described in detail by way of the embodiments described above, the technique of the present disclosure is not limited thereto. The technique of the present disclosure may be modified or combined with one another in various ways without departing from the scope thereof.

For example, the substrate processing apparatus 10 according to the embodiments of the present disclosure can be applied to not only a semiconductor manufacturing apparatus capable of manufacturing a semiconductor device but also to an apparatus capable of processing a glass substrate such as an LCD apparatus. Further, for example, a processing of the substrate may include a process such as a CVD process, a PVD process, a process of forming an oxide film, a process of forming a nitride film, a process of forming a film containing a metal, an annealing process, an oxidation process, a nitridation process and a diffusion process. Further, the technique of the present disclosure may also be applied to various substrate processing apparatuses such as an exposure apparatus, a coating apparatus, a drying apparatus, and a heating apparatus.

According to some embodiments of the present disclosure, it is possible to confirm the gas line whose gas flow rate is to be edited by the user.

What is claimed is:

1. A method of manufacturing a semiconductor device, comprising
(a) displaying, on a recipe edit screen configured to create a recipe comprising a plurality of steps, a parameter setting region configured to set control parameters at least comprising a gas flow rate of a flow rate controller and a gas pattern screen configured to set an opening/closing state of a valve;
(b) editing the recipe on the recipe edit screen; and
(c) processing a substrate by performing the recipe edited in (b),
wherein, in (b), when the gas flow rate of the flow rate controller is set on the parameter setting region, a flow rate controller on the gas pattern screen in association with the flow rate controller whose gas flow rate is set on the parameter setting region is clearly specified.

2. The method of claim 1, wherein (b) comprises (b-1) setting the opening/closing state of the valve on the gas pattern screen, and
wherein, when an arbitrary valve is selected on the gas pattern screen in (b-1), an opening/closing state of the arbitrary valve is determined.

3. The method of claim 2, wherein, when the opening/closing state of the arbitrary valve is being set in (b-1), a prohibition condition for prohibiting the arbitrary valve from being opened is confirmed, and
wherein an alarm display is performed when the arbitrary valve meets the prohibition condition.

4. The method of claim 2, wherein, when the arbitrary valve for which a prohibition condition for prohibiting the arbitrary valve from being opened is set is selected on the gas pattern screen, the prohibition condition is displayed on the gas pattern screen.

5. The method of claim 2, wherein, in (b-1), when the arbitrary valve is selected on the gas pattern screen, a gas pipe connected to the arbitrary valve selected on the gas pattern screen is clearly specified.

6. The method of claim 1, wherein the gas pattern screen is configured such that at least a plurality of valves located within a range from a supply system to an exhaust system are displayed, and
wherein a source material is supplied to a reaction chamber through the supply system and an inner pressure of the reaction chamber is reduced to a vacuum atmosphere through the exhaust system.

7. The method of claim 6, wherein the gas pattern screen is further configured such that one or more icons for the flow rate controller, a vaporizer, an exhaust apparatus and a pressure regulator are capable of being displayed.

8. The method of claim 7, wherein the one or more icons for the flow rate controller, the vaporizer, the exhaust apparatus and the pressure regulator are displayed such that parameters related thereto are capable of being set on the gas pattern screen.

9. The method of claim 1, wherein the recipe edit screen is further configured to be capable of setting parameters related to at least one of a temperature or a pressure as the control parameters.

10. The method of claim 1, wherein the recipe edit screen further comprises a switching button configured to switch types of the control parameters to be displayed.

11. The method of claim 1, wherein one or more among a temperature, a pressure, the valve, the flow controller, a transfer, an external equipment and a signal are selected as the control parameters to be displayed on the recipe edit screen.

12. The method of claim 1, wherein the recipe edit screen is further configured to display the parameter setting region and the gas pattern screen for each of the plurality of steps, and
wherein the recipe edit screen comprises a step setting region configured to set steps of the gas pattern screen and the parameter setting region to be displayed.

13. The method of claim 12, wherein the step setting region is configured to display whether or not a setting of the control parameters of each of the plurality of steps has been changed.

14. The method of claim 12, wherein an alarm display is performed on the step setting region when the control parameters are set to meet an interlock condition.

15. A display method comprising
(a) displaying, on a recipe edit screen configured to edit a recipe comprising a plurality of steps, a step contents setting region displayed for each step and comprising a parameter setting region configured to set control parameters at least comprising a gas flow rate of a flow rate controller and a step setting region configured to set a step of the step contents setting region to be displayed,
wherein whether or not a setting of the control parameters of each of the plurality of steps has been changed is displayed on the step setting region.

16. The display method of claim 15, wherein an alarm display is performed on the step setting region when the control parameters are set to meet an interlock condition.

17. The display method of claim 15, wherein contents set for a predetermined step is displayed on the step contents setting region when the predetermined step is selected in the step setting region.

18. A non-transitory computer-readable recording medium storing a program that causes, by a computer, a substrate processing apparatus provided with a controller capable of creating a recipe by setting a plurality of parameters and capable of processing a substrate by executing the recipe, to perform a process comprising the method of claim 1.

19. A substrate processing apparatus provided with a controller capable of creating a recipe by setting a plurality of parameters and capable of processing a substrate by executing the recipe,
wherein the controller is configured to be capable of performing:
(a) displaying, on a recipe edit screen configured to edit the recipe comprising a plurality of steps, a parameter setting region configured to set control parameters at least comprising a gas flow rate of a flow rate controller and a gas pattern screen configured to set an opening/closing state of a valve; and
(b) editing the recipe on the recipe edit screen,
wherein, in (b), when the gas flow rate of the flow rate controller is set on the parameter setting region, a flow rate controller on the gas pattern screen in association with the flow rate controller whose gas flow rate is set on the parameter setting region is clearly specified.
